(19) United States
(12) Patent Application Publication
(10) Pub. No.: US 2015/0008732 A1
(43) Pub. Date: Jan. 8, 2015

(54) SIGNAL TRANSMISSION CIRCUIT

(71) Applicant: Rohm Co., Ltd., Kyoto (JP)

(72) Inventor: Yoshiaki Fujimoto, Kyoto (JP)

(21) Appl. No.: 14/321,848

(22) Filed: Jul. 2, 2014

(30) Foreign Application Priority Data
Jul. 5, 2013 (JP) 2013141899

(51) Int. Cl. H03K 17/081

(52) U.S. Cl. CPC H03K 17/08104
USPC 307/9.1; 327/109

(57) ABSTRACT

A signal transmission circuit includes an output transistor with a first terminal connected to an output terminal of an output signal; a driver circuit configured to drive a control terminal of the output transistor in response to an input signal; a voltage follower configured to generate a first voltage by buffering the output signal; a voltage divider configured to generate a second voltage by dividing the first voltage; and a capacitor connected between a supply terminal of the second voltage and the control terminal of the output transistor.

### CROSS-REFERENCE TO RELATED APPLICATION

This application is based upon and claims the benefit of priority from Japanese Patent Application No. 2013-141899, filed on Jul. 5, 2013, the entire contents of which are incorporated herein by reference.

### TECHNICAL FIELD

The present disclosure relates to a signal transmission circuit.

### BACKGROUND

FIG. 8 illustrates a circuit diagram of an example for an open-drain output circuit in the related art. A system that connects a capacitor Cₛᵣ between a gate and a drain of an output transistor Mₒᵤₜ (which may be referred to as a capacitance feedback system) has been employed to adjust a slew rate of an open-drain output circuit.

However, the capacitance feedback system in the related art requires a high withstand voltage of the capacitor Cₛᵣ when a power supply voltage VCC₁ as a pull-up source of an output signal OUT is high. The withstand voltage of the capacitor Cₛᵣ may be increased, for example, by stacking capacitance elements and increasing film thicknesses thereof. However, the above increasing method may result in the problem of an increase in size of the capacitor Cₛᵣ. In particular, this problem becomes significant as the capacitance required for the capacitor Cₛᵣ increases, which is one of the hindrance factors in the integration of semiconductor devices.

In addition, in a capacitance feedback system of the related art, if noise is superimposed on the output signal OUT, the noise may be directly transmitted to the gate of the output transistor Mₒᵤₜ due to capacitive coupling via the capacitor Cₛᵣ, which may result in the collapse of an output waveform.

### SUMMARY

The present disclosure provides some embodiments of a signal transmission circuit which is capable of adjusting a slew rate without causing an increase in circuit size and deterioration of noise resistance, a semiconductor device including such a circuit, a functional module including such a device, an electronic apparatus including such a module, and a vehicle including such an apparatus.

According to one embodiment of the present disclosure, there is provided a signal transmission circuit including an output transistor including a first terminal connected to an output terminal of an output signal; a driver circuit configured to drive a control terminal of the output transistor in response to an input signal; a voltage follower configured to generate a first voltage by buffering the output signal; a voltage divider configured to generate a second voltage by dividing the first voltage; and a capacitor connected between a supply terminal of the second voltage and the control terminal of the output transistor.

In one embodiment, the signal transmission circuit may further include a current limiting resistor connected between the output terminal and an input terminal of the voltage follower.

In one embodiment, the signal transmission circuit may further include a clamping unit configured to clamp a voltage applied to the control terminal of the output transistor to a predetermined value.

In one embodiment, the signal transmission circuit may further include a logic fixing resistor connected between the control terminal of the output transistor and a fixed voltage potential terminal.

In one embodiment, the signal transmission circuit may further include a bias unit, connected between the first terminal of the output transistor and the output terminal, configured to fix a voltage applied to the first terminal of the output transistor to a predetermined value.

In one embodiment, the signal transmission circuit may further include a backflow prevention element connected between the first terminal of the output transistor and the output terminal.

According to another embodiment of the present disclosure, there is provided a semiconductor device integrated with the above-described signal transmission circuit.

According to still another embodiment of the present disclosure, there is provided a functional module including the above-described semiconductor device and a microcomputer configured to conduct communications via the signal transmission circuit.

According to still another embodiment of the present disclosure, there is provided an electronic apparatus including the above-described functional module and a LIN (Local Interconnect Network) bus connected with the functional module.

According to yet another embodiment of the present disclosure, there is provided a vehicle including the above-described electronic apparatus and a CAN (Controller Area Network) bus connected with the electronic apparatus.

### BRIEF DESCRIPTION OF THE DRAWINGS

FIG. 1 is a block diagram of a configuration example for a vehicle, according to an embodiment of the present disclosure.

FIG. 2 is a block diagram of a configuration example for a functional module, according to one embodiment of the present disclosure.

FIG. 3 is a block diagram of a configuration example for a semiconductor device, according to one embodiment of the present disclosure.

FIG. 4 is a circuit diagram of a configuration example for an output driving unit, according to one embodiment of the present disclosure

FIG. 5 is a voltage waveform diagram of an example for the node voltages, according to one embodiment of the present disclosure.

FIG. 6 illustrates an external view of a configuration example for the vehicle, according to one embodiment of the present disclosure

FIGS. 7A to 7D are circuit diagrams of modifications to a signal transmission circuit, according to some embodiments of the present disclosure.

FIG. 8 is a circuit diagram for an example of an open-drain output circuit in the related art.

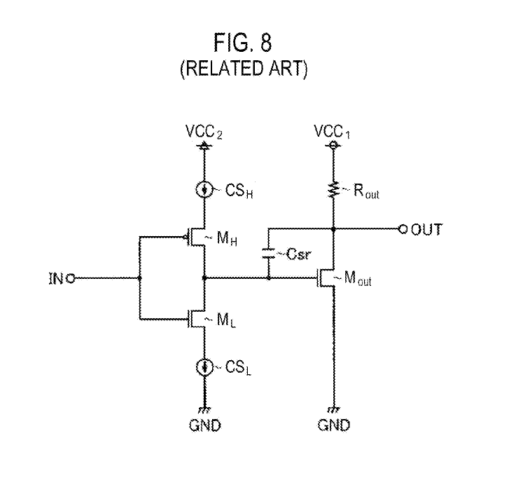

### DETAILED DESCRIPTION

### Overall Configuration

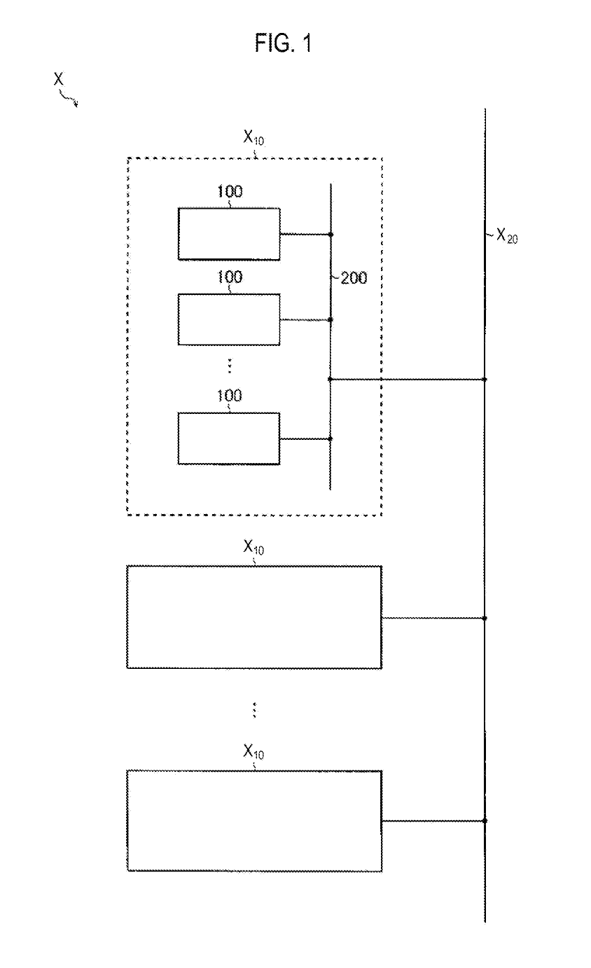

FIG. 1 is a block diagram of a configuration example for a vehicle X, according to an embodiment of the present disclosure. The vehicle X of this configuration example includes a plurality of electronic apparatuses X₁₀ and a CAN bus X₂₀. The electronic apparatuses X₁₀ are CAN nodes (e.g., various light groups, doors, air conditioners, car audios, sunroofs, and the like) connected in common to the CAN bus X₂₀. In addition, within each of the electronic apparatuses X₁₀, a sub network including a plurality of functional modules 100 and a LIN bus 200 is implemented.

The CAN bus X₂₀ may be a two-wire (e.g., a differential-type) signal transmission path for exchanging information between the electronic apparatuses X₁₀ according to a multi-communication protocol. Specifically, the CAN bus X₂₀ is used as a transmission path of signals (e.g., signals associated with a traveling speed of the vehicle X for use in power train and chassis controls, an engine rpm, a brake status, information on an error status, and the like) that require a high transmission rate and a high noise resistance.

The functional modules 100 are LIN nodes (e.g., sensor modules, actuator modules, and the like) connected in common to the LIN bus 200.

The LIN bus 200 may be a one-wire (i.e., a single end-type) signal transmission path for exchanging information between the functional modules 100 according to a multi-communication protocol. Specifically, the LIN bus 200 is used as a transmission path of signals (e.g., signals associated with opening and closing a power window, adjusting a side mirror, adjusting an electric seat, detecting door lock, and the like) that require a high transmission rate and a high noise resistance. The LIN bus 200 is connected to the CAN bus X₂₀ via a CAN/LIN gateway (or bridge).

Thus, using the CAN bus X₂₀ and the LIN bus 200 in in-vehicle networking may prevent an increase in the number of wirings associated with electronic control of the vehicle X, which may be helpful for cost reduction, weight reduction, and reliability improvement of the vehicle X.

### Functional Module

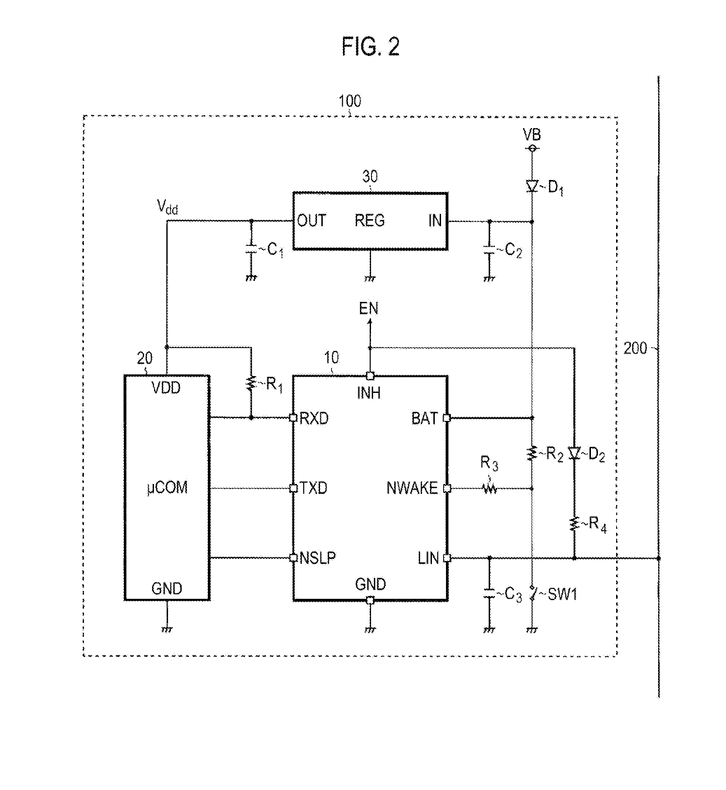

FIG. 2 is a block diagram of a configuration example for the functional module 100, according to one embodiment of the present disclosure. The functional module 100 is a LIN node (which may be either a master node or a slave node, but is assumed to be a master node in this configuration example) connected to the LIN bus 200 and includes a semiconductor device 10, a microcomputer 20, a regulator IC 30, resistors R₁ to R₄, capacitors C₁ to C₃, diodes D₁ and D₂, and a switch SW₁.

The semiconductor device 10 is a silicon monolithic integrated circuit (e.g., LIN transceiver IC) formed by integrating a signal transmission circuit for bidirectional signal exchange between the microcomputer 20 and the LIN bus 200. The semiconductor device 10 includes various external terminals (i.e., BAT, NWAKE, LIN, INH, GND, RXD, TXD, and NSLP) as means for establishing external electric connections. The BAT pin is a power supply terminal. The NWAKE pin is a local wake-up input terminal. The LIN pin is an LIN bus input/output terminal. The INH pin is an inhibition output terminal. The GND pin is a ground terminal. The RXD pin is an output terminal for reception data. The TXD pin is an input terminal for transmission data. The NSLP pin is a sleep control input terminal.

The microcomputer 20 is a logic circuit which operates with a power supply voltage V_{dd}, which is applied by the regulator IC 30 to a VDD pin, and conducts a bidirectional communication with the LIN bus 200 via the semiconductor device 10 (specifically, a signal transmission circuit implemented therein). The microcomputer 20 is connected to the RXD pin, the TXD pin, and the NSLP pin of the semiconductor device 10.

The regulator IC 30 generates the power supply voltage V_{ad} (e.g., +5V) by lowering a battery voltage VB (e.g., +25 to +27V, rated at +40V) and outputs the generated power supply voltage V_{ad} via an OUT pin. An example of the regulator IC 30 may include a switching regulator, a series regulator, or the like.

The connection relations between the discrete components outside the semiconductor device 10, the microcomputer 20, and the regulator IC 30 are described below in detail. A first end of the resistor R₁ is connected to the VDD pin of the microcomputer 20 and the OUT pin of the regulator IC 30 while a second end thereof is connected to the RXD pin of the semiconductor device 10. A first end of the resistor R₂ is connected to the BAT pin of the semiconductor device 10. A second end of the resistor R₂ and a first end of the resistor R₃ are both connected to the ground terminal via the switch SW₁. A second end of the resistor R₃ is connected to the NWAKE pin of the semiconductor device 10. A first end of the resistor R₄ (e.g., having resistance from 900Ω to 1.1 kΩ) is connected to the LIN pin of the semiconductor device 10.

An anode of the diode D₁ is connected to a supply terminal of the battery voltage VB. A cathode of the diode D₁ is connected to an IN pin of the regulator IC 30 and the BAT pin of the semiconductor device 10. An anode of the diode D₂ is connected to the INH pin of the semiconductor device 10. A cathode of the diode D₂ is connected to a second end of the resistor R₄.

The capacitor C₁ is an output smoothing element which is connected between the OUT pin of the regulator IC 30 and the ground terminal. The capacitor C₂ is also an output smoothing element which is connected between the IN pin of the regulator IC 30 and the ground terminal. The capacitor C₃ is a wiring capacitance (e.g., 1 nF in a master node, and 220 pF in a slave node) which is connected between the LIN pin of the semiconductor device 10 and the ground terminal.

However, the above connections are described as an example and may be modified in different manners. For example, a pull-up source of the LIN pin via the resistor R₄ and the diode D₂ may be the BAT pin, rather than the INH pin. If the functional module 100 is a slave node, such discrete components may be omitted.

### Semiconductor Device

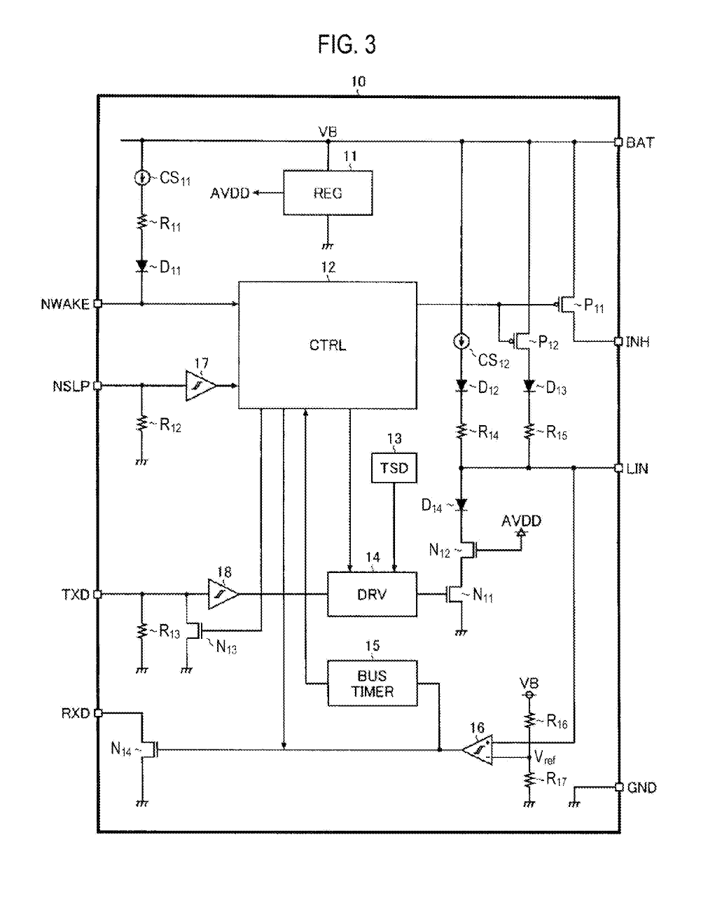

FIG. 3 illustrates a block diagram of a configuration example for the semiconductor device 10, according to one embodiment of the present disclosure. The semiconductor device 10 in this configuration example includes a constant voltage generating unit 11, a control unit 12, a temperature protecting unit 13, an output driving unit 14, a bus timer unit 15, a comparator 16, Schmitt triggers 17 and 18, resistors R₁₁ to R₁₇, diodes D₁₁ to D₁₄, N-channel type MOSFETs (Metal Oxide Semiconductor Field Effect Transistors) N₁₁ to N₁₄, P-channel type MOSFETs P₁₁ and P₁₂, and current sources CS₁₁ and CS₁₂.

The constant voltage generating unit 11 is connected between the BAT pin and the GND pin, and generates an internal power supply voltage AVDD (e.g., +5V) by lowering the battery voltage VB. An example of the constant voltage generating unit 11 may include a switching regulator, a series regulator, or the like.

The control unit 12 has a function of switching a sleep mode into a standby mode when detecting a falling edge (i.e., SW₁ is ON in FIG. 2) of a local wake-up signal that is inputted to the NWAKE pin (i.e., local wake-up function). In this case, the control unit 12 makes the TXD pin a low level to inform the microcomputer 20 that the sleep mode is switched to the standby mode in response to the local wake-up. In addition, the control unit 12 sets the RXD pin to a low level when the sleep mode is switched to the standby mode. Further, the control unit 12 has a function of switching the sleep mode to the standby mode by monitoring an output signal of the bus timer unit 15 (specifically, a remote wake-up signal that is inputted to the LIN pin) (i.e., remote wake-up function). Furthermore, upon detecting a falling edge of a sleep control signal inputted to the NSLP pin, the control unit 12 prohibits outputting of a signal at the LIN pin, resets a local or remote wake-up flag at the TXD pin, and resets a wake-up request at the RXD pin.

If the junction temperature of the semiconductor device 10 exceeds a predetermined upper limit, the temperature protection unit 13 outputs a temperature protection signal indicating that the junction temperature exceeds the upper limit to the output driving unit 14, so as to forcibly stop outputting a signal from the LIN pin.

The output driving unit 14 controls turning on and off the transistor N₁₁ in response to a transmission data signal inputted to the TXD pin. Here, the output driving unit 14 generates a gate signal for the transistor N₁₁ to allow the output signal from the LIN pin to be varied with a desired slew rate. In addition, the output driving unit 14 has a function of receiving instructions from the control unit 12 and the temperature protecting unit 13 and stopping the control of turning on and off the transistor N₁₁ upon detecting a sleep mode and temperature abnormality.

The bus timer unit 15 monitors a comparison signal generated in the comparator 16, detects whether or not the remote wake-up signal is inputted to the LIN pin, and informs the control unit 12 of a result of the detection.

The comparator 16 generates the comparison signal by comparing a supply voltage (i.e., received data signal) of the LIN pin that is inputted to a non-inverted input terminal (+) with a predetermined reference voltage V_{ref} that is inputted to an inverted input terminal (−). The comparison signal is of a high level when the supply voltage of the LIN pin is greater than the reference voltage V_{ref}, and a low level when the supply voltage of the LIN pin is smaller than the reference voltage V_{ref}. In addition, the comparator 16 may have a hysteresis characteristic.

The Schmitt trigger 17 transmits the sleep control signal, which is inputted to the NSLP pin, to the control unit 12. The Schmitt trigger 18 transmits the transmit data signal, which is inputted to the TXD pin, to the output driving unit 14. In addition, both of the Schmitt triggers 17 and 18 may have a hysteresis characteristic.

A drain of the transistor N₁₁ is connected to the LIN pin via the transistor N₁₂ and the diode D₁₄. A source of the transistor N₁₁ is connected to the ground terminal. A gate of the transistor N₁₁ is connected to an output terminal of the output driving unit 14. The transistor N₁₁ having connections as described above acts as an output transistor forming an open-drain output stage for the LIN pin.

A source of the transistor N₁₂ is connected to the drain of the transistor N₁₁. A drain of the transistor N₁₂ is connected to a cathode of the diode D₁₄. A gate of the transistor N₁₂ is connected to a supply terminal of the internal power supply voltage AVDD. An example of the transistor N₁₂ may include a high withstand voltage element (e.g., DMOSFET (Double-diffused MOSFET having a 50V withstand voltage) which is not broken when a high withstand voltage (e.g., +40V) is applied to the LIN pin. The transistor N₁₂ having connections as described above acts as a biasing unit for fixing a voltage applied to the drain of the transistor N₁₁ to be a predetermined value (e.g., VADD−Vₜₕ (on-threshold voltage of MOSFET)). Therefore, a low withstand voltage element (e.g., a MOSFET having a 5V withstand voltage) can be used as the transistor N₁₁ without deterioration of the characteristics of the transistor N₁₁ which may be caused by a high voltage.

The cathode of the diode D₁₄ is connected to the drain of the transistor N₁₂. An anode of the diode D₁₄ is connected to the LIN pin. The diode D₁₄ having connection as described above acts as a backflow prevention element for preventing a reverse current from flowing from the ground terminal to the LIN pin although a negative voltage (e.g., −27V) is applied to the LIN pin.

A drain of the transistor N₁₃ is connected to the TXD pin. A source of the transistor N₁₃ is connected to the ground terminal. A gate of the transistor N₁₃ is connected to the control unit 12. The transistor N₁₃ acts as a switch element for switching whether to lower the TXD pin to a low level in response to an instruction from the control unit 12.

A drain of the transistor N₁₄ is connected to the RXD pin. A source of the transistor N₁₄ is connected to the ground terminal. A gate of the transistor N₁₄ is connected to an output terminal of the comparator 16. The transistor N₁₄ acts as an output transistor forming an open-drain output stage for the RXD pin.

A source of the transistor P₁₁ is connected to the BAT pin. A drain of the transistor P₁₁ is connected to the INH pin. A gate of the transistor P₁₁ is connected to the control unit 12. The transistor P₁₁ is turned off in the sleep mode of the semiconductor device 10 while it is turned on in the standby mode of the semiconductor device 10. Accordingly, the transistor P₁₁ acts as a switch element for switching whether to raise the INH pin to a high level (i.e., the battery voltage VB) according to an instruction from the control unit 12. For example, a signal outputted from the INH pin can be used as an enable signal EN of each component of the functional module 100 (see FIG. 2).

A source of the transistor P₁₂ is connected to the BAT pin. A drain of the transistor P₁₂ is connected to an anode of the diode D₁₃. A gate of the transistor P₁₂ is connected to the control unit 12. A cathode of the diode D₁₃ is connected to a first end of the resistor R₁₅ (for example, 30 kΩ). A second end of the resistor R₁₅ is connected to the LIN pin. The transistor P₁₂ is turned off in the sleep mode of the semiconductor device 10 while it is turned on in the standby mode of the semiconductor device 10. As such, the transistor P₁₂, the diode D₁₃, and the resistor R₁₅ form a pull-up circuit for pulling-up the LIN pin to the BAT pin in the standby mode of the semiconductor device 10.

An anode of the diode D₁₂ is connected to the BAT pin via the current source CS₁₂. A cathode of the diode D₁₂ is connected to a first end of the resistor R₁₄. A second end of the resistor R₁₄ is connected to the LIN pin. As such, the current source CS₁₂, the diode D₁₂, and the resistor R₁₄ form a pull-up circuit for pulling-up the LIN pin to the BAT pin when the battery voltage VB is applied to the semiconductor device 10, regardless of whether the semiconductor device 10 is in the standby mode or in the sleep mode.

A first end of the resistor R₁₁ is connected to the BAT pin via the current source CS₁₁. A second end of the resistor R₁₁ is connected to an anode of the diode D₁₁. A cathode of the diode D₁₁ is connected to the NWAKE pin. As such, the current source CS₁₁, the resistor R₁₁, and the diode D₁₁ form a pull-up circuit for pulling-up the NWAKE pin to the BAT pin. The resistor R₁₂ serves as a pull-down resistor connected between the NSLP pin and the ground terminal. The resistor R₁₃ serves as a pull-down resistor connected between the TXD pin and the ground terminal.

A first end of the resistor R₁₆ is connected to the supply terminal of the battery voltage VB (i.e., the BAT pin). A second end of the resistor R₁₆ and a first end of the resistor R₁₇ are connected to the inverted input terminal (−) of the comparator 16. A second end of the resistor R₁₇ is connected to the ground terminal. The resistors R₁₆ and R₁₇ having connections as described above form a voltage divider for generating the reference voltage V_{ref} from the battery voltage VB.

### Output Driving Unit

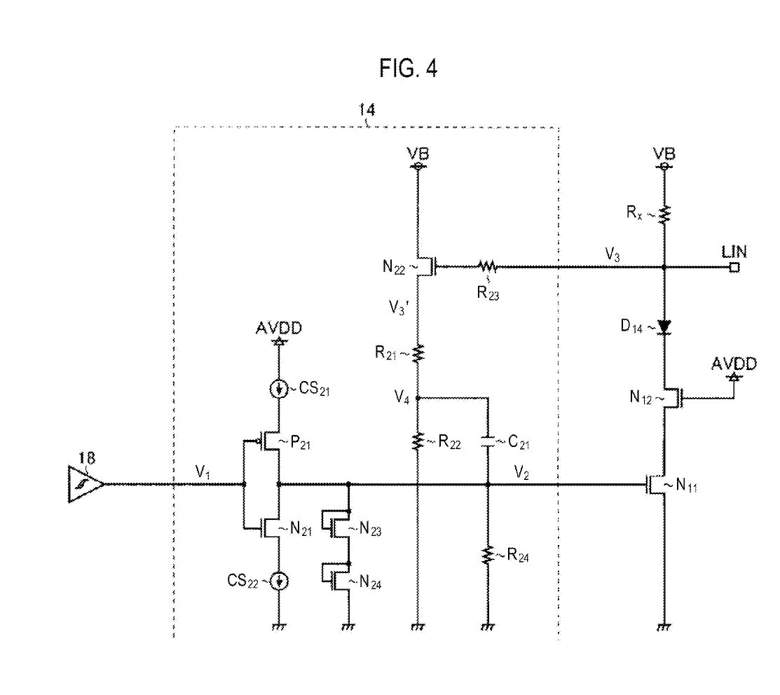

FIG. 4 is a circuit diagram of a configuration example for the output driving unit 14, according to one embodiment of the present disclosure. The output driving unit 14 in this configuration example includes resistors R₂₁ to R₂₄, a capacitor C₂₁, N-channel type MOSFET N₂₁ to N₂₄, a P-channel type MOSFET P₂₁ and current sources CS₂₁ and CS₂₂.

A source of the transistor P₂₁ is connected to the supply terminal of the internal power supply voltage AVDD via the current source CS₂₁. A drain of the transistor P₂₁ and a drain of the transistor N₂₁ are both connected to the gate of the transistor N₁₁ (i.e., a supply terminal of a node voltage V₂). A source of the transistor N₂₁ is connected to the ground terminal via the current source CS₂₂. Gates of the transistors P₂₁ and N₂₁ are both connected to an output terminal of a Schmitt trigger 18 (i.e., a supply terminal of a node voltage V₁). The transistors P₂₁ and N₂₁ and the current sources CS₂₁ and CS₂₂ having connections as described above form a driver circuit (i.e., an inverter circuit) for driving a gate signal of the transistor N₁₁ (i.e., the node voltage V₂) in response to an input signal (i.e., the node voltage V₁).

A drain of the transistor N₂₂ is connected to the supply terminal of the battery voltage VB. A source of the transistor N₂₂ is connected to a first end of the resistor R₂₁ (i.e., a supply terminal of a node voltage V₃′). A gate of the transistor N₂₂ is connected to the LIN pin (i.e., a supply terminal of a node voltage V₃) via the resistor R₂₃. The transistor N₂₂ having connections as described above forms a voltage follower (or a source follower) for buffering an output signal that is outputted from the LIN pin and generating a first voltage (i.e., the node voltage V₃′ (=V₃−Vₜₕ)).

The resistor R₂₃ connected between the LIN pin (corresponding to a supply terminal of the output signal) and the gate of the transistor N₂₂ (corresponding to an input terminal of the voltage follower) serves as a current limiting resistor for protecting the gate of the transistor N₂₂. The LIN pin is connected as being pulled-up to the supply terminal of the battery voltage VB via a resistor Rx (corresponding to one of pull-up resistors connected to the entire LIN bus 200, which has up to 16 nodes for all master nodes and slave nodes, such as the resistor R₄ of FIG. 2 and the resistors R₁₄ and R₁₅ of FIG. 3).

The first end of the resistor R₂₁ is connected to the supply terminal of the node voltage V₃′. A second end of the resistor R₂₁ and a first end of the resistor R₂₂ are connected to each other, and a connection node thereof corresponds to an output terminal of a node voltage V₄. A second end of the resistor R₂₂ is connected to the ground terminal. The resistors R₂₁ and R₂₂ having connections as described above form a voltage dividing circuit for generating a second voltage (i.e., the node voltage V₄ (={R₂₂/(R₂₁+R₂₂)}×V₃′) by dividing the first voltage (i.e., the node voltage V₃′). The capacitor C₂₁ is connected between a supply terminal of the node voltage V₄ and the gate of the transistor N₁₁.

A drain and a gate of the transistor N₂₃ are both connected to the gate of the transistor N₁₁. A drain and a gate of the transistor N₂₄ are both connected to a source of the transistor N₂₃. A source of the transistor N₂₄ is connected to the ground terminal. The transistors N₂₃ and N₂₄ having connections as described above form a clamping unit for clamping the node voltage V₂ applied to the gate of the transistor N₁₁ to a predetermined upper limit. A Zener diode or the like may be used as the clamping unit.

The resistor R₂₄ serves as a pull-down resistor connected between the gate of the transistor N₁₁ and the ground terminal. This allows the node voltage V₂ to be fixed at a low level (i.e., a logic level to turn off the transistor N₁₁) if an output of the driver circuit is undefined.

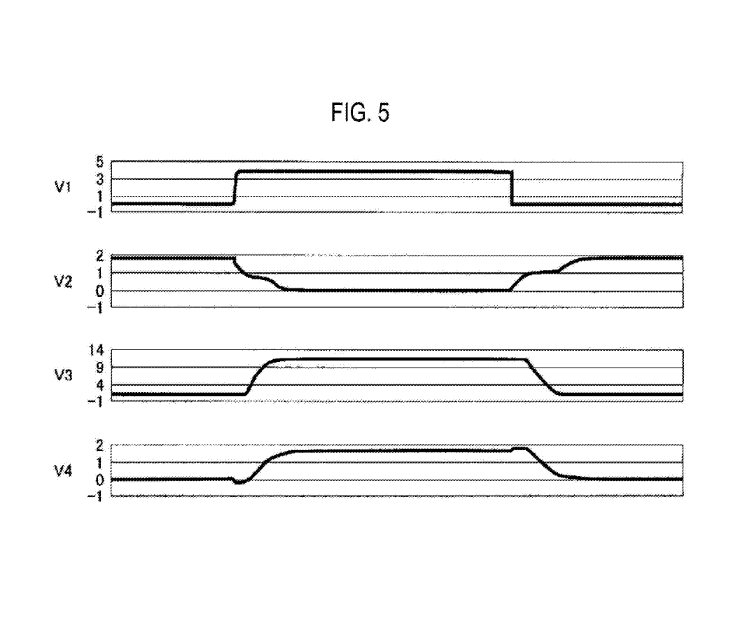

Operation of the above-configured output driving unit 14 is described below with reference to FIG. 5. FIG. 5 is a voltage waveform diagram of an example for the node voltages V₁ to V₄, according to one embodiment of the present disclosure. When the node voltage V₁ rises from a low level to a high level, the transistor P₂₁ is turned off and the transistor N₂₁ is turned on. As a result, a constant current flows from the gate of the transistor N₁₁ toward the ground terminal via the transistor N₂₁ and the current source CS₂₂, and the node voltage V₂ falls to a low level accordingly. When the node voltage V₂ falls to a low level, the transistor N₁₁ is turned off and the node voltage V₃ goes to a high level accordingly.

Conversely, when the node voltage V₁ falls from the high level to the low level, the transistor P₂₁ is turned on and the transistor N₂₁ is turned off. As a result, a constant current flows from the supply terminal of the internal power supply voltage AVDD toward the gate of the transistor N₁₁ via the current source CS₂₁ and the transistor P₂₁, and the node voltage V₂ rises to a high level accordingly. When the node voltage V₂ rises to a high level, the transistor N₁₁ is turned on and the node voltage V₃ falls to a low level accordingly.

The capacitance feedback system in the related art where the node voltage V₃ of the LIN pin is directly applied to the capacitor C₂₁ requires a high withstand voltage of the capacitor C₂₁ and has a problem of noise sneaking through the capacitor C₂₁.

In contrast, in the output driving unit 14 of this configuration example, the node voltage V₃ is not directly applied to the capacitor C₂₁, but the node voltage V₄ which is a voltage sufficiently lowered by the source follower and the voltage divider is applied to the capacitor C₂₁. This configuration allows the capacitance of the capacitor C₂₁ and the withstand voltage of an element to be lower than those in the capacitance feedback system of the related art, which can result in reduction in an area of the element.

With the output driving unit 14 of this configuration example, since noise superimposed on the output signal of the LIN pin can be attenuated in the transistor N₂₂ and the resistor R₂₁, disturbance of an output waveform due to noise sneaking through the capacitor C₂₁ can be reduced.

Thus, with the signal transmission circuit including the output driving unit 14 of this configuration example, it is possible to properly adjust a slew rate of a high voltage output signal outputted from the LIN pin without causing circuit upsizing and deterioration of noise resistance. For example, with the output driving unit 14 of this configuration example, it is possible to satisfy an output signal slew rate (e.g., 1τ to 5τ in time constant notation) defined in the LIN standard without depending on the resistance (e.g., 500Ω to 1 kΩ) of the pull-up resistor Rx connected to the LIN pin and the wiring capacitance (e.g., 1 nF to 10 nF).

In addition, although high resistance of the resistors R₂₁ and R₂₂ may be set in order to reduce a circuit current of the output driving unit 14, setting the resistance too high may likely oscillate the output signal (i.e., the node voltage V3). Therefore, the resistance of the resistors R21 and R22 may be set as high (e.g., tens of kI) as possible within a range which does not cause oscillation of the output signal.

### Application to Vehicle

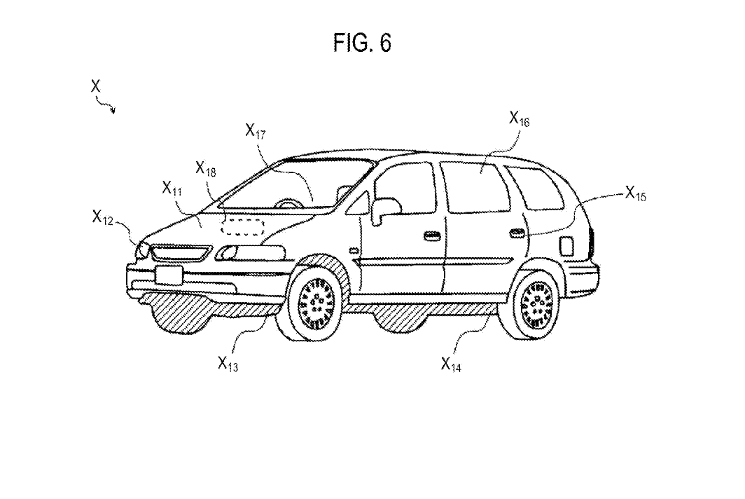

FIG. 6 illustrates an external view of a configuration example for the vehicle X, according to one embodiment of the present disclosure. The vehicle X in this configuration example is implemented with various electronic apparatuses X₁₁ to X₁₈ (corresponding to the electronic apparatuses X₁₀ described above) which operate with the battery voltage VB. The mounting positions of the electronic apparatuses X₁₁ to X₁₈ in FIG. 6 are depicted for the convenience of illustration, and may be different from practical positions.

The electronic apparatus X₁₁ is an engine control unit configured to perform engine-related controls (e.g., injection control, electronic throttle control, idle control, oxygen sensor heater control, automatic cruise control, and the like).

The electronic apparatus X₁₂ is a lamp control unit configured to control turning on and off an HID (High Intensity Discharged) lamp, a DRL (Daytime Running Lamp), and the like.

The electronic apparatus X₁₃ is a transmission control unit configured to perform transmission-related controls.

The electronic apparatus X₁₄ is a body control unit configured to perform controls related to movement of the vehicle X (e.g., ABS (Anti-lock Brake System) control, EPS (Electric Power Steering) control, electronic suspension control, and the like).

The electronic apparatus X₁₅ is a security control unit configured to control door lock and crime prevention alarm.

The electronic apparatus X₁₆ is an electronic apparatus, which is mounted in the vehicle X in a shipping stage at a factory, such as standard equipment and maker optional accessories, for example, a wiper, an electric door mirror, a power window, a damper (i.e., shock absorber), an electric sunroof, an electric sheet, and the like.

The electric apparatus X₁₇ is an optional electric apparatus, which is mounted in the vehicle X, such as user option accessories, for example, car A/V (Audio/Video) equipment, a car navigation system, ETC (Electronic Toll Collection) system, and the like.

The electronic apparatus X₁₈ is an electronic apparatus equipped with a high withstand voltage motor, such as a car blower, an oil pump, a water pump, a battery cooling fan, and the like.

The above-described semiconductor device 10 may be incorporated, as an LIN transceiver IC, into any of the electronic apparatuses X₁₁ to X₁₈.

### Other Modifications

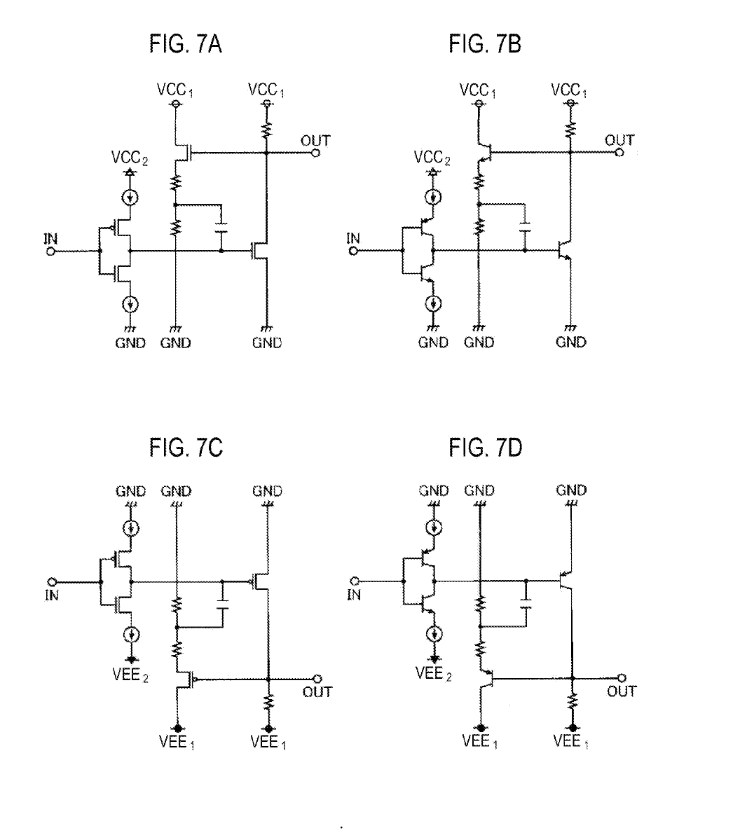

In addition to the above-described embodiments, various technical features disclosed herein may be modified in different manners without departing from the spirit and scope of the present disclosure. For example, among various circuit elements such as an NMOS type, an NPN type, a PMOS type, and a PNP type illustrated in FIGS. 7A, 7B, 7C, and 7D, respectively, which form the signal transmission circuit, a MOSFET is interchangeable with a bipolar transistor, and a polarity of an N-channel type (i.e., NPN type) is changeable with a P-channel type (i.e., PNP type). In the examples of FIGS. 7A to 7D, it is assumed that voltages applied to various nodes have a magnitude relationship of VCC1>VCC2>GND>VEE2>VEE1.

As described above, the present disclosure can be applied to a LIN transceiver, and the like.

According to the present disclosure in some embodiments, it is possible to provide a signal transmission circuit which is capable of adjusting a slew rate without causing increase in circuit size and deterioration of noise resistance, a semiconductor device including the circuit, a functional module including the device, an electronic apparatus including the module, and a vehicle including the apparatus.

While certain embodiments have been described, these embodiments have been presented by way of example only, and are not intended to limit the scope of the disclosure. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A signal transmission circuit comprising:
an output transistor including a first terminal connected to an output terminal of an output signal;
a driver circuit configured to drive a control terminal of the output transistor in response to an input signal;
a voltage follower configured to generate a first voltage by buffering the output signal;
a voltage divider configured to generate a second voltage by dividing the first voltage; and
a capacitor connected between a supply terminal of the second voltage and the control terminal of the output transistor.

2. The signal transmission circuit of claim 1, further comprising a current limiting resistor connected between the output terminal and an input terminal of the voltage follower.

3. The signal transmission circuit of claim 1, further comprising a clamping unit configured to clamp a voltage applied to the control terminal of the output transistor to a predetermined value.

4. The signal transmission circuit of claim 1, further comprising a logic fixing resistor connected between the control terminal of the output transistor and a fixed voltage potential terminal.

5. The signal transmission circuit of claim 1, further comprising a bias unit, connected between the first terminal of the output transistor and the output terminal, configured to fix a voltage applied to the first terminal of the output transistor to a predetermined value.

6. The signal transmission circuit of claim 1, further comprising a backflow prevention element connected between the first terminal of the output transistor and the output terminal.

7. A semiconductor device integrated with the signal transmission circuit of claim 1.

8. A functional module comprising:
the semiconductor device of claim 7; and
a microcomputer configured to conduct communications via the signal transmission circuit.

9. An electronic apparatus comprising:
the functional module of claim 8; and
a LIN (Local Interconnect Network) bus connected with the functional module.

10. A vehicle comprising:
the electronic apparatus of claim 9; and
a CAN (Controller Area Network) bus connected with the electronic apparatus.
